(19) United States
(12) Patent Application Publication
(10) Pub. No.: US 2012/0326277 A1
(43) Pub. Date: Dec. 27, 2012

(54) POWER SEMICONDUCTOR DEVICE AND MANUFACTURING METHOD THEREOF

(76) Inventors: Seung-Chul LEE, Bucheon-si (KR); Eun-Taek KIM, Incheon (KR)

(21) Appl. No.: 13/451,822

(22) Filed: Apr. 20, 2012

(30) Foreign Application Priority Data
Jun. 21, 2011 (KR) 10-2011-0060131

(51) Int. Cl. H01L 29/00; H01L 21/425

(52) U.S. Cl. 257/607; 438/533; 257/E21.473; 257/E29.001

(57) ABSTRACT

A power semiconductor device and a manufacturing method thereof are provided. The method of manufacturing a power semiconductor device includes the steps: (a) forming a cell structure on a first conductivity type semiconductor substrate; (b) implanting second conductivity type ions onto the rear surface of the first conductivity type semiconductor substrate and activating to form an electrode region; and (c) implanting ions creating first conductivity type with a doping concentration higher than that of the semiconductor substrate and activating to form a high-concentration ion implanted region at a position below the cell structure and on the electrode region. Accordingly, it is possible to form a field stop layer regardless of conditions for forming an electrode region (for example, a P-type collector region) and thus to optimize stable breakdown voltage characteristics and device characteristics.

### CROSS-REFERENCE TO RELATED APPLICATIONS

This application is based on and claims priority under 35 USC 119 from Korean Patent Application No. 10-2011-0060131 filed Jun. 21, 2011, which is hereby expressly incorporated by reference into the present application.

### BACKGROUND

1. Technical Field

The present invention relates to a power semiconductor device and a manufacturing method thereof.

2. Related Art

Semiconductor devices in the field of power electronics such as insulated gate bipolar transistors (IGBT), power metal-oxide-semiconductor field effect transistors (power MOSFET), and various types of thyristors have been studied for the purpose of satisfying various requirements (for example, high reverse blocking voltage, low conduction loss, high switching speed, and low switching loss) in various industrial fields as well as vehicle applications.

Among these semiconductor devices in the field of power electronics, an IGBT (Insulated Gate Bipolar Transistor) which is a power semiconductor device having both a high speed switching characteristic of a high-power MOSFET and a high current characteristic of a BJT (Bipolar Junction Transistor) have attracted attention in recent years.

There are various types in structures of IGBT. A field stop type (FS) IGBT can be understood as a soft punch-through type IGBT. The FS IGBT is a combination of an NPT (Non-Punch Through) IGBT structure and a PT (Punch Through) IGBT structure. Accordingly, it is known that the FS IGBT has various advantages of both technologies such as lower saturation voltage (Vce,sat), high switching speed, easy parallel operation, and ruggedness.

The field stop layer of the FS IGBT is formed using an Epi wafer or a diffused wafer but has a disadvantage that the starting wafer is expensive. Accordingly, a method of implanting ions through the rear surface of a semiconductor substrate to form a field stop layer has been used in recent years. Since the atomic weight of phosphorus or arsenic element generally used as N-type impurities is great, it is not easy to implant such ions to form a junction in a region several μm or deeper. Therefore, protons are used instead of phosphorus or arsenic. The proton implantation has a problem in that when an annealing temperature is excessively high and thus the proton implanted regions are completely activated, the implanted protons do not create donors. To solve this problem, protons are implanted to a specific depth of several μm or more and then an activation process is performed at an appropriate annealing temperature (for example, in the range of 300° C. to 500° C.) to activate the proton created shallow thermal donors, whereby an N conductivity type field stop layer is formed.

Since a P-type collector region (that is, electrode region) is also formed in the rear surface of the semiconductor substrate through ion implantation and diffusion, an appropriate activation process has to be performed for activation of the implanted dopant.

In general, the activation temperature of the implanted ions to form a collector region is set to be as high as possible. This is intended to enhance injection efficiency of holes and thus to reduce power consumption in conduction mode. However, in consideration of the melting point of metal layer (for example, emitter metal electrode) present on the semiconductor front surface, the activation temperature has to be set to an appropriate temperature range (for example, a range of 350° C. to 550° C.).

However, when the collector region is formed after the field stop layer is formed, the high activation temperature at which the collector region is formed causes a problem. This is because the activation temperature for the later-formed collector region is higher than the activation temperature for the previously-formed field stop layer. In this case, the protons do not create donors due to excessive activation thereof and thus do not perform the function of a field stop layer correctly.

To solve this problem, a method of lowering the activation temperature for forming the collector region or performing a laser annealing process enabling the activation of only a rear surface is used. However, these methods still restrict the setting of optimal process conditions for manufacturing a power semiconductor device.

The above-mentioned related art is technical information possessed to make the invention or learned in the course of making the invention by the inventor, and cannot thus be said to be technical information known to the public before filing the invention.

### SUMMARY

An advantage of some aspects of the invention is that it provides a power semiconductor device and a manufacturing method thereof, which can form a field stop layer regardless of electrode region forming conditions by first performing a process of forming an electrode region (for example, a P-type collector region) of a semiconductor device and then performing a process of forming a field stop layer through ion implantation and thus can achieve stable breakdown voltage characteristics and optimized device characteristics.

Another advantage of some aspects of the invention is that it provides a power semiconductor device and a manufacturing method thereof, which can easily adjust the amount of ions implanted to form a field stop layer and a collector region and the activation temperature thereof to freely adjust the characteristics of the power semiconductor device.

Still another advantage of some aspects of the invention is that it provides a power semiconductor device and a manufacturing method thereof, which can easily implant ions to an accurate position to form a stable field stop layer and can guarantee an accurate junction depth of the field stop layer.

Other advantages of the invention will be easily understood from the following description.

According to an aspect of the invention, a method of manufacturing a semiconductor device and a semiconductor device manufactured through the use of the method.

The method of manufacturing a power semiconductor device includes the steps: (a) forming a cell structure on a first conductivity type semiconductor substrate; (b) implanting first conductivity type ions or second conductivity type ions onto the rear surface of the first conductivity type semiconductor substrate and activating to form an electrode region; and (c) implanting first conductivity type ions and activating to form a high-concentrated first conductivity type region with a doping concentration higher than that of the semiconductor substrate at a position below the cell structure and on the electrode region.

The method may further include a step of forming a metal electrode on the rear surface of the semiconductor substrate so as to be electrically connected to the electrode region after the step of (c).

A grinding process of reducing the thickness of the semiconductor device to a predetermined thickness may be performed between the steps of (a) and (b).

The first conductivity type region may be a field stop layer or a buffer layer serving to suppress expansion of a depletion layer.

The ions implanted to form the first conductivity type region may include one or more species of proton, helium, and deuteron.

An activation temperature at which the electrode region is formed may be higher than the activation temperature at which the first conductivity type region is formed.

The first conductivity type may be one of a P type and an N type and the second conductivity type may be the other of the P type and the N type.

Other aspects, features, and advantages of the invention will become apparent from the accompanying drawings, the appended claims, and the detailed description

According to the aspect of the invention, it is possible to form a field stop layer regardless of electrode region forming conditions by first performing a process of forming an electrode region (for example, a P-type collector region) of a semiconductor device and then performing a process of forming a field stop layer through ion implantation and thus to achieve stable breakdown voltage characteristics and optimized device characteristics.

It is also possible to easily adjust the amount of ions implanted to form a field stop layer and a collector region and the activation temperature thereof to freely adjust the characteristics of the power semiconductor device.

It is also possible to easily implant ions to an accurate position to form a stable field stop layer and can guarantee an accurate junction depth of the field stop layer.

### BRIEF DESCRIPTION OF THE DRAWINGS

FIG. 1 is a diagram illustrating a sectional configuration of a field stop IGBT according to the related art.

FIG. 2 is a diagram illustrating a doping profile of the section taken along A-A′ of FIG. 1.

FIG. 3 is a diagram illustrating a sectional configuration of a field stop IGBT in which a field stop layer is formed through an ion implantation process according to the related art.

FIG. 4 is a diagram illustrating a doping profile of the section taken along B-B′ of FIG. 3.

FIG. 5 is a flowchart illustrating the flow of a power semiconductor device manufacturing process according to an embodiment of the invention.

FIGS. 6A and 6B are cross-sectional views illustrating the power semiconductor device manufacturing process according to the embodiment of the invention.

### DESCRIPTION OF EXEMPLARY EMBODIMENTS OF THE INVENTION

The invention can be modified in various forms and specific embodiments will be described and shown below. However, the embodiments are not intended to limit the invention, but it should be understood that the invention includes all the modifications, equivalents, and replacements belonging to the concept and the technical scope of the invention. When it is determined that detailed description of known techniques associated with the invention makes the gist of the invention obscure, the detailed description will not be made.

Terms such as “first” and “second” can be used to describe various elements, but the elements are not limited to the terms. The terms are used only to distinguish one element from another element.

The terms used in the following description are intended to merely describe specific embodiments, but not intended to limit the invention. An expression of the singular number includes an expression of the plural number, so long as it is clearly read differently. The terms such as “include” and “have” are intended to indicate that features, numbers, steps, operations, elements, components, or combinations thereof used in the following description exist and it should thus be understood that the possibility of existence or addition of one or more other different features, numbers, steps, operations, elements, components, or combinations thereof is not excluded.

If it is mentioned that an element such as a layer, a region, or a substrate is disposed “on” another element or extends “onto” another element, it should be understood that the element is disposed directly on another element or extends directly onto another element, or still another element is interposed therebetween. On the contrary, if it is mentioned that an element is disposed “directly on” another element or extends “directly onto” another element, it should be understood that still another element is not interposed therebetween. If it is mentioned that an element is “connected to” or “coupled to” another element, it should be understood that still another element may be interposed therebetween, as well as that the element may be connected or coupled directly to another element. On the contrary, if it is mentioned that an element is “connected directly to” or “coupled directly to” another element, it should be understood that still another element is not interposed therebetween.

Relative terms such as “below”, “above”, “upper”, “lower”, “horizontal”, “lateral”, and “vertical” can be used to describe the relation of an element, a layer, or a region relative to another element, another layer, or another region as shown in the drawings. The terms are intended to include another orientation of a device relative to an orientation shown in the drawings.

The exemplary embodiments of the invention will be described now in detail with reference to the accompanying drawings. Although an insulating gate bipolar transistor (IGBT) will be mainly described below, the technical concept of the invention can be identically or similarly applied or extend to various types of semiconductor devices such as power MOSFET.

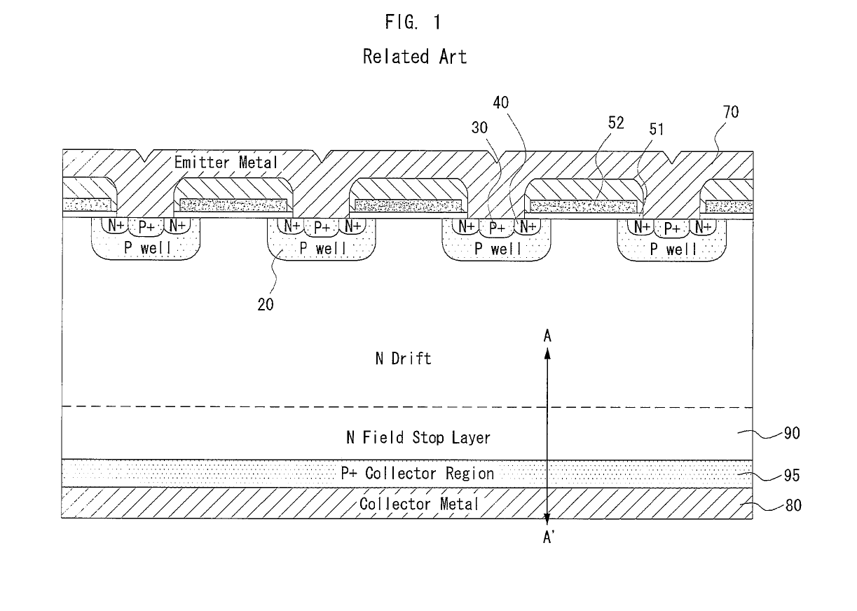

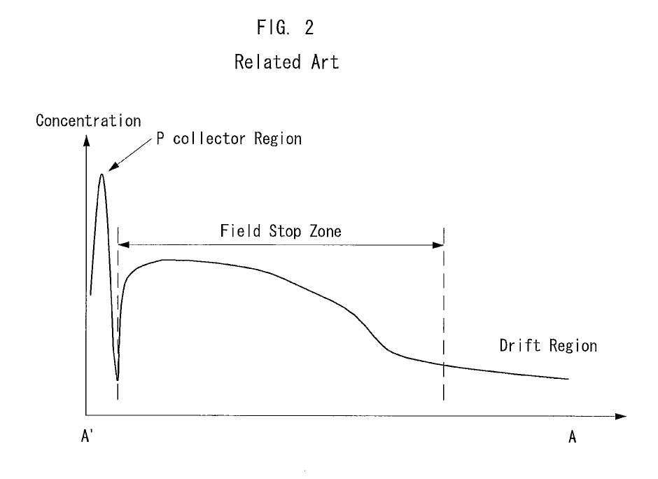

FIG. 1 is a diagram illustrating a sectional configuration of a field stop IGBT according to the related art. FIG. 2 is a diagram illustrating a doping profile of the section taken along A-A′ of FIG. 1.

Referring to FIG. 1, a field stop IGBT has a structure in which P-type wells 20 are formed on a drift region formed in an N-type semiconductor substrate and plural N-type wells 40 which are high-concentration impurity regions are formed in each P-type well 20. A high-concentration P-type ion region 30 may further be formed in the P-type well 20.

A gate oxide film 51 is formed on the part between the neighboring P-type wells 20, a gate poly-electrode 52 is formed on the gate oxide film 51, an interlayer insulating film is formed to cover the gate oxide film 51 and the gate poly-electrode 52, and an emitter metal electrode 70 is formed thereon so as to include active cells therein and to be electrically connected to the N-type wells 40 which serve as emitter regions.

An N-type field stop layer 90 is formed below the drift region, a P-type collector region 95 is formed below the N-type field stop layer 90, and a collector metal electrode 80 is formed below the P-type collector region 95.

An IGBT is a minority carrier device in which main current flows by hole carriers. That is, since hole current injected from the P-type collector region 95 moves through the lightly doped drift region, it is necessary to minimize the length of the drift region to reduce the power consumption during the forward operation.

However, in order to guarantee a breakdown voltage required for an application circuit, the drift region needs to have a sufficient length so that an extended depletion layer do not reach the P-type collector region 95. In this way, since a drift region needs to have a predetermined length or more, there is a restriction in reducing the power consumption during the operation.

To overcome this restriction, as shown in FIG. 1, a field stop IGBT in which a field stop layer 90 which is an N type region with a doping concentration higher than the doping concentration of the drift region is formed on the P-type collector region 95 is used.

In the field stop IGBT, a depletion layer extending with an application of a reverse bias is blocked by the field stop layer 90 and thus a high breakdown voltage can be achieved with only the drift region having a relatively short length, thereby achieving improved forward operation characteristics.

In order to form the field stop layer 90 below the drift region, an N-/N Epi wafer in which an N-type epitaxially-grown layer is formed on an N-type substrate is used or a diffused wafer in which an N-/N structure is formed by implanting N conductivity type ions into the lower part of an N-type semiconductor substrate and performing an diffusion process for a long time to form a deep junction is used.

When a field stop IGBT is manufactured using these methods, the section A-A′ shown in FIG. 1 exhibits a variation in doping concentration shown in FIG. 2 and the doping concentration in the field stop layer 90 has a concentration distribution in which it becomes lower as it goes closer to the drift region.

However, as described above, when a field stop IGBT is manufactured using an Epi wafer or a diffused wafer, there is a problem in that the production cost of the Epi wafer or the diffused wafer is high and thus there is a need for a method of easily manufacturing a field stop IGBT at a lower cost.

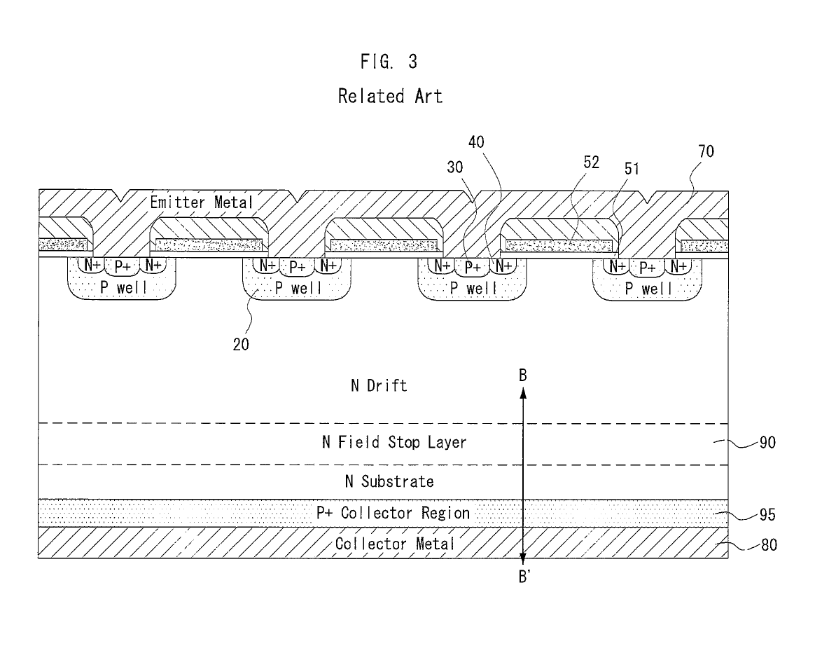

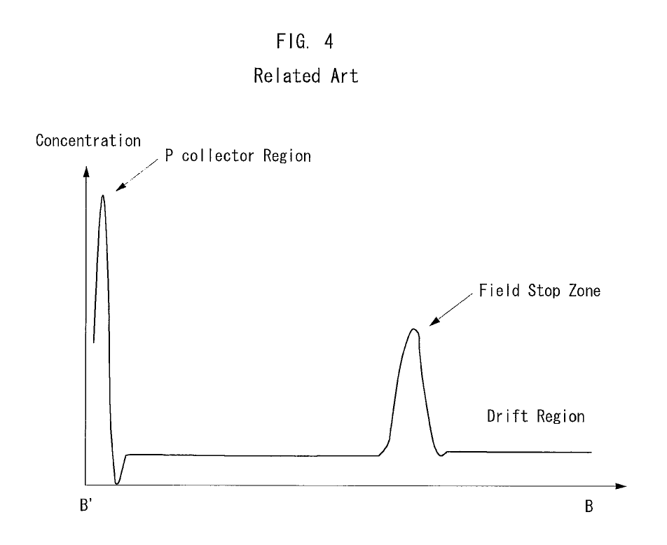

FIG. 3 is a diagram illustrating a sectional configuration of a field stop IGBT in which a field stop layer is formed through an ion implantation process according to the related art. FIG. 4 is a diagram illustrating a doping profile of the section taken along B-B′ of FIG. 3.

A cross-section of the field stop IGBT in which the field stop layer 90 is formed by implanting ions onto the rear surface of an N-type semiconductor substrate. Except that a diffusion process is performed to form the field stop layer 90 which has a doping concentration higher than that of the N-type drift region, the manufacturing process for a field stop IGBT is the same as that for an NPT (Non-Punch Through) IGBT. Ions having a small mass are used as the ions implanted to form the field stop layer 90 so as to be implanted to a relatively deep position. Examples thereof include proton, helium, and deuteron.

When the field stop IGBT is manufactured through this method, the doping concentration of the section B-B′ of FIG. 3 exhibits an doping profile in which the doping concentration is high only in the P-type collector region 95 and the field stop layer 90, as shown in FIG. 4.

In order to effectively prevent the depletion layer in the field stop layer 90 formed through the ion implantation from extending to the P-type collector region 95, the field stop layer 90 needs to be formed separated from the P-type collector region 95 by several μm or more. For reference, in case of an IGBT of a 1200 V class, the field stop layer 90 is formed separated from the P-type collector region 95 by about 5 μm to 30 μM and the concentration peak by ion implantation is in the range of 5×10¹⁴/cm³ to 1×10¹⁸/cm³.

As described above, in order to for the implanted ions to serve as donors for the field stop layer 90, the implanted ions should be annealed in the temperature range of 300° C. to 500° C. The P-type collector region to be formed separated from the field stop layer 90 by a predetermined distance should be subjected to an ion implantation process and an annealing process for activating the implanted ions.

However, the activation process of the P-type collector 95 formed after forming the field stop layer 90 is performed at a temperature as high as possible in consideration of the melting point of the emitter metal electrode 70 formed in the front region. There is a problem in that this temperature is higher than the activation temperature at which the field stop layer 90 is formed.

Therefore, a method of lowering the activation temperature for the P-type collector region 95 to be formed later or performing a laser annealing process enabling the activation of only the surface can be used so as not to affect the activation processes for forming the field stop layer 90 and the P-type collector region 95 each other. However, there is still a problem in that the setting of process conditions suitable for manufacturing a semiconductor device is restricted in spite of using these methods.

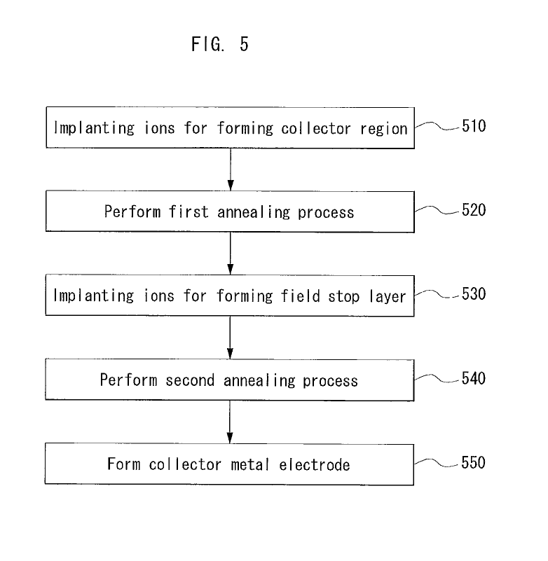

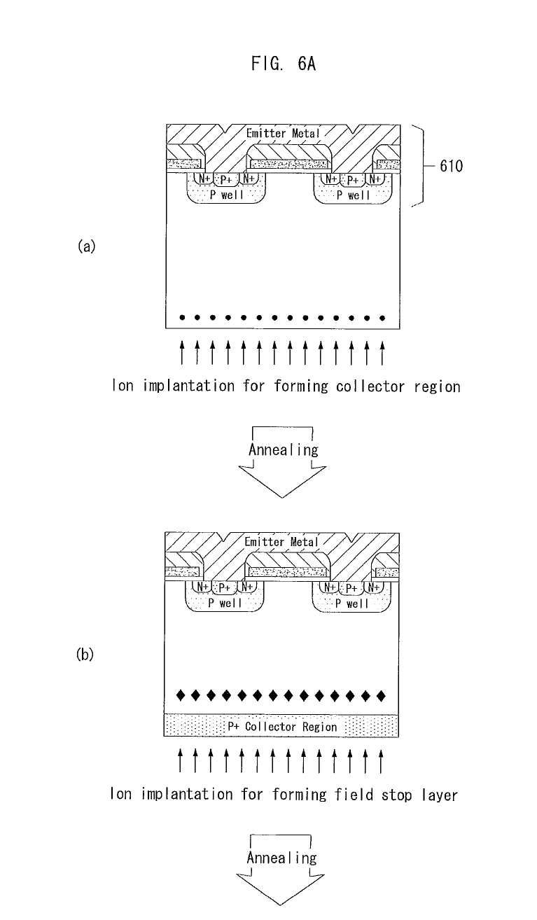

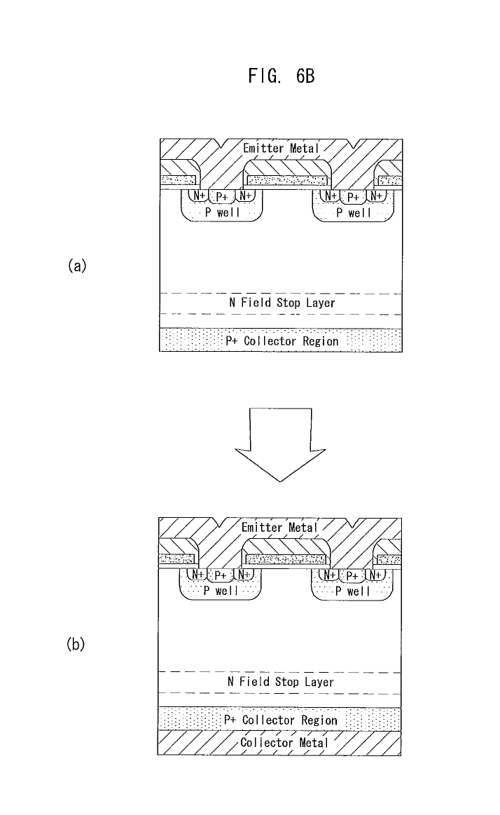

FIG. 5 is a flowchart illustrating the flow of a power semiconductor device manufacturing process according to an embodiment of the invention. FIGS. 6A and 6B are cross-sectional views illustrating the power semiconductor device manufacturing process according to the embodiment of the invention.

As described below, a power semiconductor device according to an embodiment of the invention is characterized in manufacturing processes, in that a process of forming a P-type collector region 95 at a relatively high temperature is first performed and then a process of forming a field stop layer 90 is then performed.

Referring to FIG. 5 and FIGS. 6A and 6B, in step 510, P conductivity type ions are implanted up to a predetermined depth through the rear surface of the semiconductor substrate to form the P-type collector region 95 (see (a) of FIG. 6A).

Steps of forming a cell structure 610 which is an upper structure shown in FIG. 6A can be performed before step 510. A cell structure 610 of a planar gate IGBT is shown in FIG. 6A, but a cell structure of a trench gate IGBT and the like may be employed. Although not shown in the drawings, a grinding step for reducing the thickness of the power semiconductor device to a predetermined thickness can be performed in advance.

Subsequently, in step 520, an activation process is performed at a temperature in the range of 300° C. to 500° C. to activate the implanted P conductivity type ions. The activation temperature can be set to be as high as possible in consideration of the melting point or the denaturalization of the emitter metal electrode 70 formed on the semiconductor substrate. The implanted ions can be satisfactorily activated by performing the activation process at a temperature as high as possible, whereby the power consumption during the forward operation can be minimized.

In this embodiment, since the P-type collector region 95 is formed before forming the field stop layer 90 in this way, the amount of ions to be implanted and the activation temperature can be freely set to adjust the device characteristics, similarly to the existing process of manufacturing an NPT IGBT.

In step 530, ions creating N-type region are implanted to a predetermined depth into the rear surface of the semiconductor substrate to form the field stop layer 90 (see (b) of FIG. 6A). In step 540, the annealing process is performed to activate the ion implanted region (see (b) of FIG. 6A and (a) of FIG. 6B).

In step 530, the N type trap region can be formed through the ion implantation to a depth allowing the field stop layer 90 to be separated from the P-type collector region 95 by a predetermined distance.

The temperature of the activation process performed in step 540 is typically lower than the activation temperature for the P-type collector region 95 formed in steps 510 and 520. Accordingly, since the previously-formed P-type collector region 95 is not affected, it is possible to perform the activation process optimized to form the field stop layer 90 and thus to optimize the characteristics of the field stop layer 90. It is possible to enhance the degree of freedom in characteristic adjustment of the power semiconductor device, compared with the related art in which the P-type collector region 95 is formed after forming the field stop layer 90.

In step 550, a collector electrode is formed below the P-type collector region 95 (see (b) of FIG. 6B).

In the power semiconductor device according to this embodiment, by forming the P-type collector region 95 before forming the field stop layer 90 in this way, it is possible to optimize the characteristics of the field stop layer 90 and to enhance the degree of freedom in characteristic adjustment of the power semiconductor device.

The feature in process that other ions are implanted to form the P-type collector region 95 before implanting ions for forming the field stop layer 90 provides an advantage of stably forming the field stop layer 90. That is, it is possible to achieve a relatively accurate junction depth of the field stop layer 90 due to a pre-amorphization effect caused by implanting other ions for forming the P-type collector region 95 before forming the field stop layer 90.

The method of manufacturing an IGBT employing a field stop structure has been hitherto described as an example of the method of manufacturing a power semiconductor device according to the invention, but the invention can be identically or similarly applied to various semiconductor devices such as diodes or MOS-driven thyristors which can employ the field stop structure. For example, when a diode is manufactured through the use of a thin wafer manufacturing process, the technical concept of the invention can be used in a process of forming an N conductivity type buffer for preventing a depletion layer from being extended to an N+ conductivity type region of a lower cathode region.

In this way, the method of manufacturing a power semiconductor device according to the invention can be applied to manufacturing of a power semiconductor device in which an electrode region (for example, a P-type region for IGBT or an N-type region for power MOSFET and diode) should be formed through the use of the ion implantation onto the rear surface of a semiconductor substrate and the diffusion process and a high-concentration region (for example, the field stop layer and the N conductivity type buffer) of N conductivity type ions should be formed at a position between the electrode region and the upper cell structure 610.

While the invention is described with reference to the embodiments, it will be understood by those skilled in the art that the invention can be modified and changed in various forms without departing from the concept and scope of the invention described in the appended claims.

1. A method of manufacturing a power semiconductor device, comprising:
(a) forming a cell structure on a first conductivity type semiconductor substrate;
(b) implanting first conductivity type ions or second conductivity type ions onto the rear surface of the first conductivity type semiconductor substrate and activating to form an electrode region; and
(c) implanting first conductivity type ions and activating to foam a high-concentrated first conductivity type region with a doping concentration higher than that of the semiconductor substrate at a position below the cell structure and on the electrode region.

2. The method according to claim 1, further comprising a step of forming a metal electrode on the rear surface of the semiconductor substrate so as to be electrically connected to the electrode region after the step of (c).

3. The method according to claim 1, further comprising of a back side grinding process to reduce the thickness of the semiconductor device to a predetermined thickness between the steps of (a) and (b).

4. The method according to claim 1, wherein the first conductivity type region is a field stop layer or a buffer layer serving to suppress expansion of a depletion layer.

5. The method according to claim 1, wherein the ions implanted to form the first conductivity type region include one or more species of proton, helium, and deuteron.

6. The method according to claim 1, wherein an activation temperature at which the electrode region is formed is higher than the activation temperature at which the first conductivity type region is formed.

7. The method according to claim 1, wherein the first conductivity type is one of a P type and an N type and the second conductivity type is the other of the P type and the N type.

8. A semiconductor device manufactured through the method according to claim 1.

9. A semiconductor device manufactured through the method according to claim 2.

10. A semiconductor device manufactured through the method according to claim 3.

11. A semiconductor device manufactured through the method according to claim 4.

12. A semiconductor device manufactured through the method according to claim 5.

13. A semiconductor device manufactured through the method according to claim 6.

14. A semiconductor device manufactured through the method according to claim 7.
